(19) United States
(12) Patent Application Publication
(10) Pub. No.: US 2020/0273847 A1
(43) Pub. Date: Aug. 27, 2020

(54) LED Support and LED Light Source Comprising Such Support

(71) Applicant: Vossloh-Schwabe Lighting Solutions GmbH & Co. KG, Kamp-Lintfort (DE)

(72) Inventor: Kenji Sugiura, Düsseldorf (DE)

(21) Appl. No.: 16/637,144

(22) PCT Filed: Aug. 7, 2018
(86) PCT No.: PCT/EP2018/071345

§ 371 Date: Feb. 6, 2020

(30) Foreign Application Priority Data
Aug. 7, 2017 (DE) 10 2017 117 874.0

(51) Int. Cl. H01L 25/075; H01L 33/50; H01L 33/54; H01L 33/56; H01L 33/62

(52) U.S. Cl. CPC H01L 25/0753; H01L 33/505; H01L 33/62; H01L 33/56; H01L 33/54

(57) ABSTRACT

An LED support for at least two groups R, G, B, M of semiconductor light sources r, g, b, m connected in series is provided with conductor tracks which allow series connections of the semiconductor light sources of each of the groups. Said series connections together with connected voltage or current sources form independent loops which are arranged on the LED support in a non-planar line pattern. This allows the arrangement of the semiconductor light sources on rings which are concentric to one another, wherein at least two of said rings contain semiconductor light sources which belong to at least two of the different groups. A constant brightness and light distribution is achieved over the surface of the LED light source. Necessary line bridges are formed by bonded wire bridges which directly adjoin the LED chips and bridge a line leading to a chip bonding surface.

The invention refers to an LED support for a set-up of LED light sources as well as a light source set-up with such an LED support.

An LED light source is known from WO 2009/146257 A1 that comprises multiple linear or in a circle arranged supports with LEDs placed thereon. On each support the LEDs are arranged in an electric series connection. The LEDs can be provided with a luminescent encapsulation in order to create light with a desired wavelength composition.

An LED light source with an LED support is known from WO 2016/086180 A1, on which multiple LEDs with different colors can be arranged. In one embodiment nine LEDs are arranged in a 3×3 matrix, wherein these LEDs are illuminating either green-white, blue-white or red. The LEDs are divided into two or three or multiple groups, wherein each group can comprise one or more LEDs and wherein the LED groups can be separately controlled in order to create different colors of light.

The attachment of LEDs on a flexible substrate by means of bond techniques is known from EP 1 594 171 A2.

EP 2 733 755 A1, particularly in FIG. 28, further discloses a semiconductor light source with an LED support, on which LEDs in different color compositions are alternatingly arranged on two circles that are concentric to each other respectively. In doing so, a homogenization of the color distribution at the light source can be achieved.

In LED light sources with variable color composition and/or variable brightness it is necessary to vary the currents that flow through the semiconductor light sources with variable color creation. Even if the individual LEDs or other semiconductor light sources are arranged such that, in case of a specific current application a homogeneous uniform color impression is created, the color distribution can be non-uniform in case of a different current distribution and thus a different brightness and/or a different total mixed color.

Starting therefrom it is the object of the invention to create an improved LED support as well as an improved LED light source that allows a variation of the currents that flow through semiconductors creating lights of different colors without impacting the uniformity of the color impression.

It is also an object of the invention to create an LED support that allows different assembly schema for creation of different colors or brightnesses that shall result in a uniform color impression respectively.

It is also an object of the invention to provide an LED support as well as an LED light source that can be easily equipped and that is robust in terms of handling.

At least one of these objects is solved by an LED support according to claim 1 as well as an LED light source according to claim 9.

In the inventive LED support conductor tracks are arranged on a support body comprising an electric insulating surface that are assigned to at least two different groups. Each group of conductor tracks is characterized in that the same current flows through the conductor tracks that are part of it after the assembly during operation. The conductor tracks of the group serve to connect semiconductor light sources arranged between these conductor tracks electrically in series such that the conductor tracks and the semiconductor light sources of the first group form a first current path and together with a current or voltage source connected thereto a first mesh. The semiconductor light sources and the conductor tracks of the second group form a second current path and together with a current or voltage source connected thereto a second mesh.

Preferably the semiconductor light sources of each group within the respective group have the same characteristics. Preferably they are at least configured for the creation of light with substantially equal spectral composition or equal color or equal shade of white. The semiconductor light sources of each group can be colored light sources or white light sources. For example, one series connection can be equipped with blue, another series connection with green, a further series connection with red and a least series connection with white light sources. Also the semiconductor light sources of two or more groups can be white light sources. For example, one series connection can be equipped with warm white and another series connection with neutral white and a further series connection with cold white light sources.

The individual light sources can comprise one or more LED chips with equal or different colors. Additionally, the LED light sources can comprise LED chips that emit just the desired light color or spectral composition and are then provided with a transparent cover. Additionally or alternatively in one or more series connections, light sources can be provided that comprise LED chips that create light deviating from the desired light color. Such semiconductor light sources are each provided with a cover that contains one or more luminescent substances that emit light with the desired color or provide the desired spectrum in combination with the light emitted from the LED chip under stimulation. The light substance or light substances can be configured to transform the total light emitted from the LED light source or only a portion thereof in another light that typically comprises a larger wavelength as the stimulating light originating from the LED light source.

The semiconductor light sources of the two groups are preferably arranged on two rings that are concentric to each other, wherein in at least one of the two rings semiconductor light sources of both groups are contained. In doing so, on this ring the light of the semiconductor light sources of both groups is mixed such that, in case of a change of the current of at least one of the two groups, the modified light impression extends over the total ring. This applies particularly, if the multiple light sources of the groups are regularly distributed over the respective ring. Preferably semiconductor light sources of both groups are contained in both rings. The “rings” are ring-shaped strip-shaped sections of the LED support.

Additionally, further groups can be provided consisting of further conductor tracks and semiconductor light sources. Additionally, further rings can be defined, in which semiconductor light sources of at least two groups are provided. If more than two of the mentioned rings are provided, at least in two of these rings semiconductor light sources of at least two groups are contained.

The series connections formed from each group of conductor tracks and semiconductor light sources or the meshes formed together with its respective current or voltage sources intersect each other at at least one and typically multiple intersections. In doing so, not only a uniform distribution of LED light sources over the area of the LED support with concurrently short conductor track length, but in addition a particularly simple adaptability of the assembly to different forward currents and efficiencies of the different light sources can be achieved.

Preferred is an LED support, in which all of the conductor tracks are placed on a singular common planar or domed plane such that all conductor tracks are placed in a common “conductor plane”. In this case the intersections of the conductor tracks are preferably formed by bond wires. Preferably this applies to all of the intersections. At such an intersection the ends of two conductor tracks facing each other are connected with each other by a bond wire that forms a bond wire bridge spanning a conductor track extending underneath. The bond wire bridges can be created with the same device with which bond wires between the conductor track and the semiconductor light sources are placed for connecting the semiconductor light sources. In doing so, the manufacturing process gets simple and clear.

In one embodiment at least some and preferably all bond wire bridges are placed with a distance to the semiconductor light sources that is no larger than the distance of the semiconductor light source to a bond area connected with a conductor track that serves for connection with a bond wire connected with the semiconductor light source. Preferably the distance of the bond wire bridge from the adjacent semiconductor light source is not larger than the length of the bond wire that serves for connection of the semiconductor light source. Additionally or alternatively, the distance of the bond wire bridge from the semiconductor light source, e.g. the LED chip, is not larger than the length of the bond wire bridge. Additionally or alternatively, the distance of the bond wire bridge to the conductor area, on which the semiconductor light source is placed, is not larger than the length of the bond wire bridge. The length of the bond wire bridge is the distance of the two bond locations of the bond wire of the bond wire bridge from each other. The length of the bond wire is larger than the length of the bond wire bridge. Preferably no conductor track is spanned by a bond wire that serves for current supply of the semiconductor light source. By compliance of at least one, preferably multiple of the conditions mentioned above, it can be achieved that large leakage distances are observed between conductor tracks, particularly the conductor tracks of different groups such that the electric insulation of the different meshes against each other is provided. It is additionally achieved that the semiconductor light sources including the adjacent bond wire bridges can be covered with a blur of cover material that is not larger as it is anyway necessary for covering a semiconductor light source including its current supplying bond wire. The blur can be additionally substantially round, wherein the reliable encapsulation of the adjacent bond wire bridge can be assured without problems without the occurrence of shadow effects.

Additionally, preferably all bond wire bridges (preferably without exceptions) are arranged such that they span exclusively conductor tracks that lead to a conductor area, on which the semiconductor light source is placed or can be placed (chip bond places). Such conductor areas, i.e. such chip bond areas have preferably a rectangular contour and serve for the mechanical attachment of the semiconductor light source. Additionally, they serve at least preferably for electric connection and thus for the current supply to the semiconductor light source. Between the bond wire and the spanned conductor track preferably no insulating element is placed. The gap is preferably exclusively filled with cured cover material.

By compliance of at least one of the above-mentioned conditions, the bond wires that serve as bond wire bridges and the bond wires that serve for connection of the adjacent semiconductor light sources can be accommodated under one and the same primary cover of the respective semiconductor light source.

The primary cover is preferably a cured accumulation (blur) of cover material, e.g. on silicon basis that is applied in flowable, e.g. liquid, semi-fluid or pasty form as shapeless mass onto the semiconductor light source in order to cover and enclose it. In doing so, some cover material reaches the LED support and coats it around the semiconductor light source. Such cover material then forms a substantially spherical domed material accumulation that surrounds the bond wires and the semiconductor light source and also fills the gap between the bond wire bridge and the conductor track placed underneath. The cover material can contain a luminescent material if needed and can also go without it. Preferably the cover material accumulation comprises a circular contour, wherein the radius is preferably only just large enough that the bond wire connecting the semiconductor light source is enclosed by the cover material.

The presented concept allows providing of robust LED light sources with protected bond wire bridges without the need to provide separate protection measures for protecting of the bond wire bridges.

Additionally, the arrangement of the bond wire bridges in direct proximity to the semiconductor light sources allows a flexible equipment of the support such that one and the same support can be used for providing different light sources. This applies particularly, if the distances of the areas of the conductor tracks provided for attachment of a bond wire bridge are so close to the area of a conductor track serving for receipt of the semiconductor light source such that the areas of the bond wire bridge can also be used for connection of a bond wire leading to the semiconductor light source.

Details of embodiments of the invention can be derived from the drawings, the description of its figures or from the dependent claims. It shows:

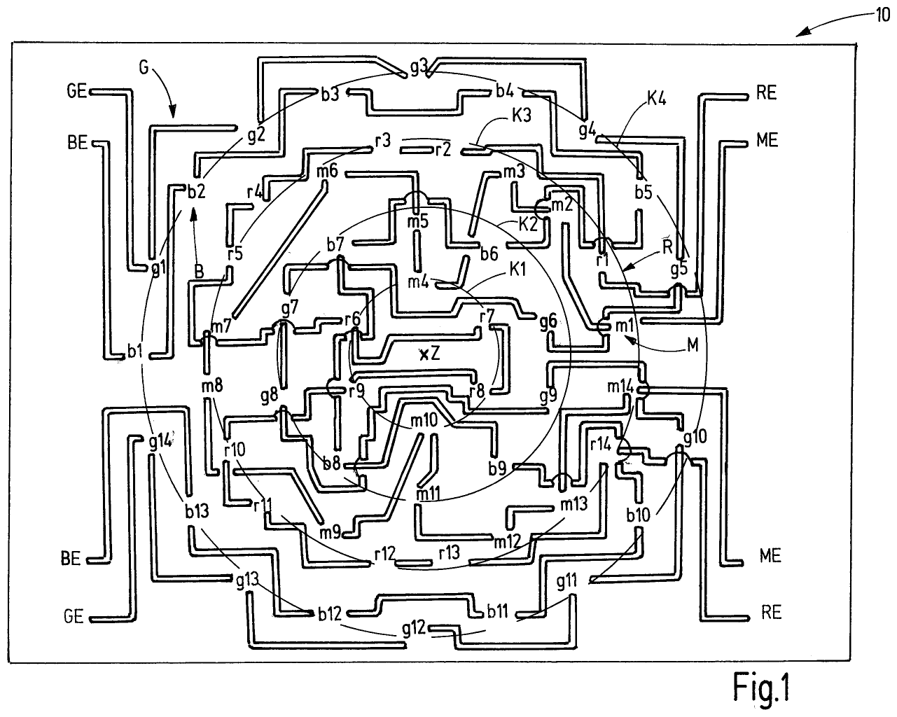

FIG. 1 the LED support with conductor tracks and assembly locations for semiconductor light sources in schematic illustration,

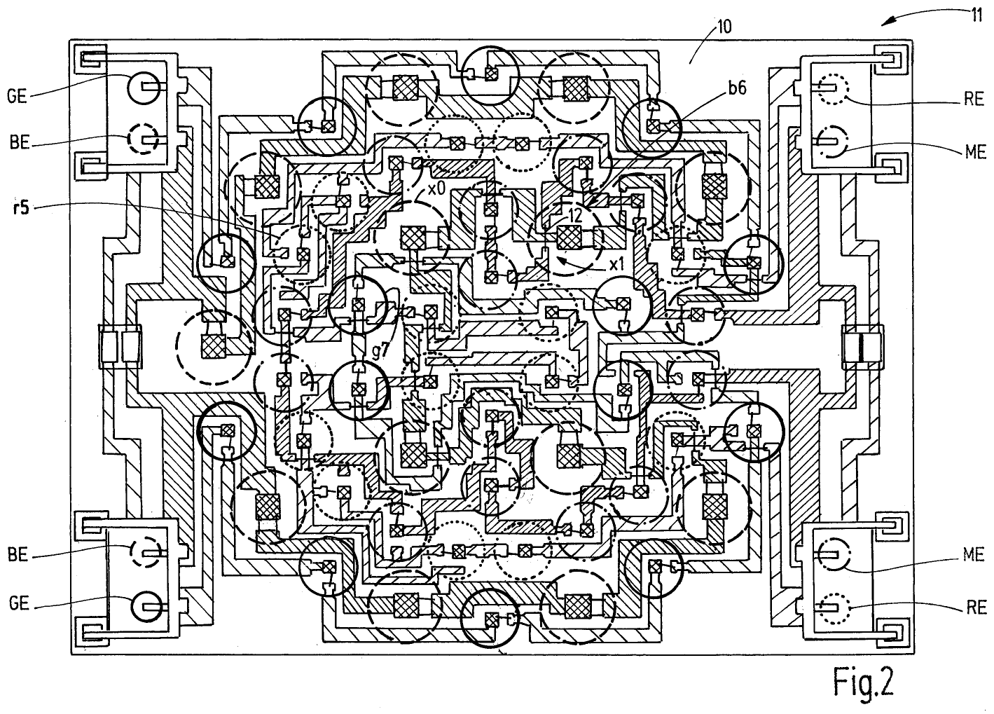

FIG. 2 an LED light source in schematic illustration set up with an LED support according to FIG. 1,

FIG. 2a a conductor track configuration at a location of the LED support according to FIG. 2,

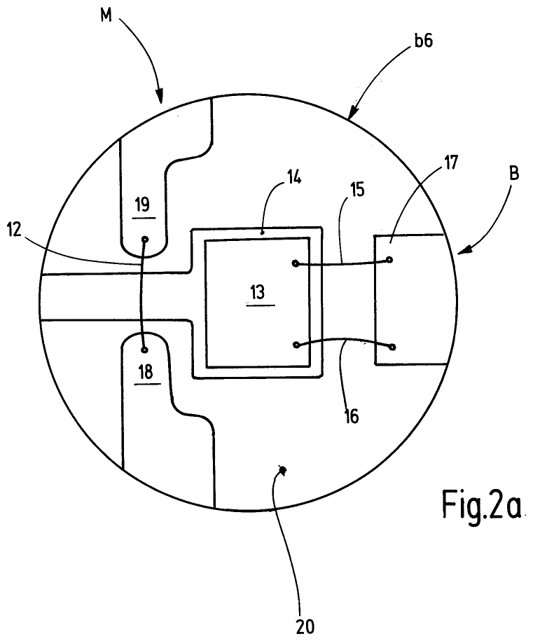

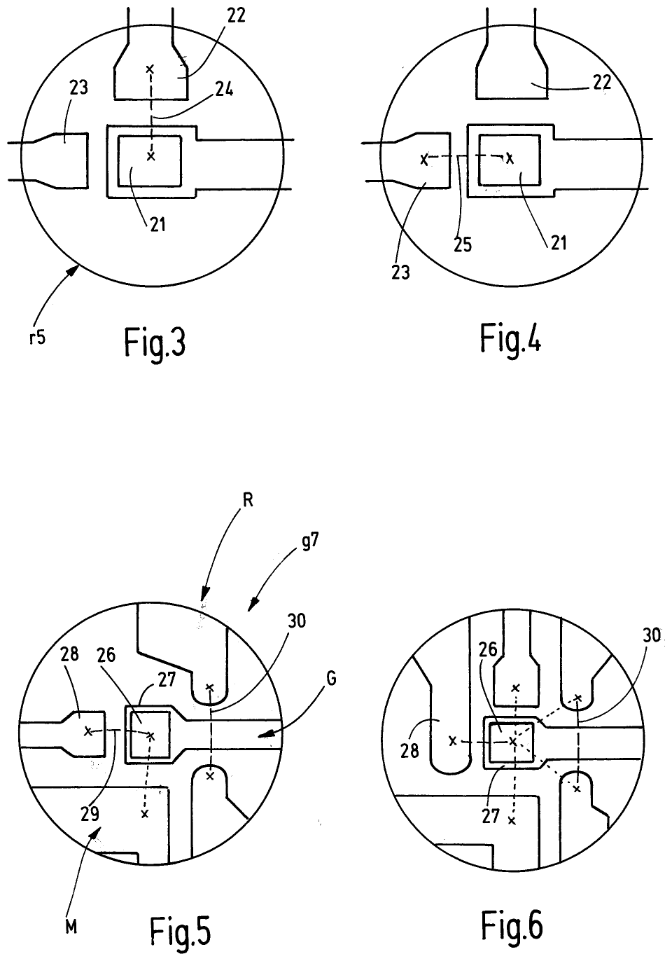

FIG. 3 a conductor track configuration at a location of the LED support according to FIG. 2 in a first connection possibility in schematic illustration,

FIG. 4 a conductor track configuration according to FIG. 3 in a different connection,

FIG. 5 a further conductor track configuration at a semiconductor light source with different connection possibilities in schematic illustration,

FIG. 6 a further modified conductor track configuration at a semiconductor light source with different connection possibilities in schematic illustration,

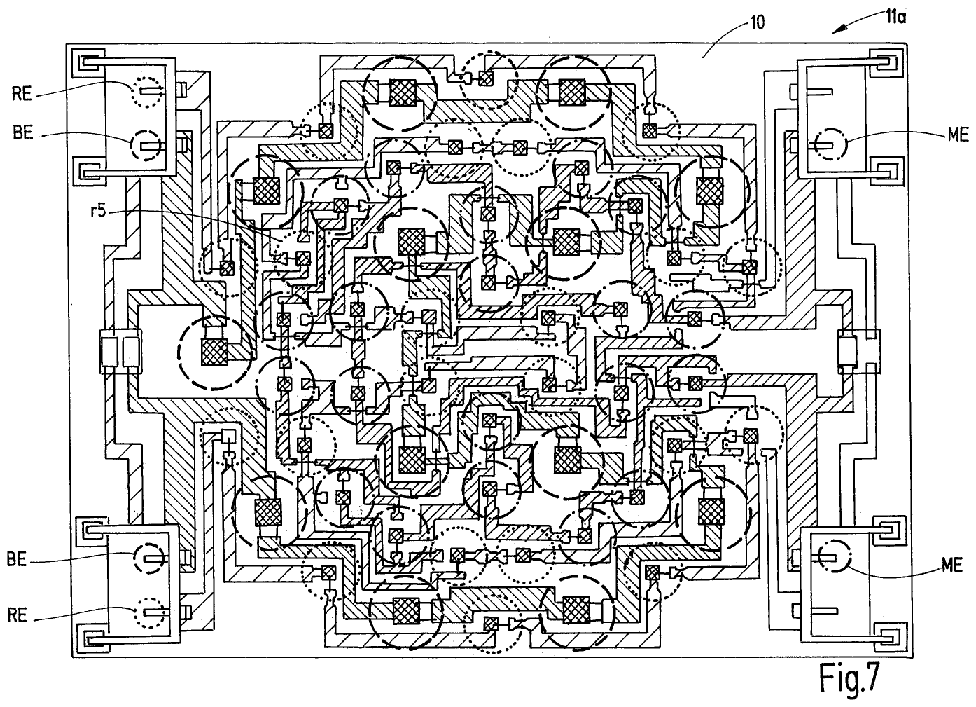

FIG. 7 an LED light source with the LED light carrier according to FIG. 1 in modified assembly in schematic illustration,

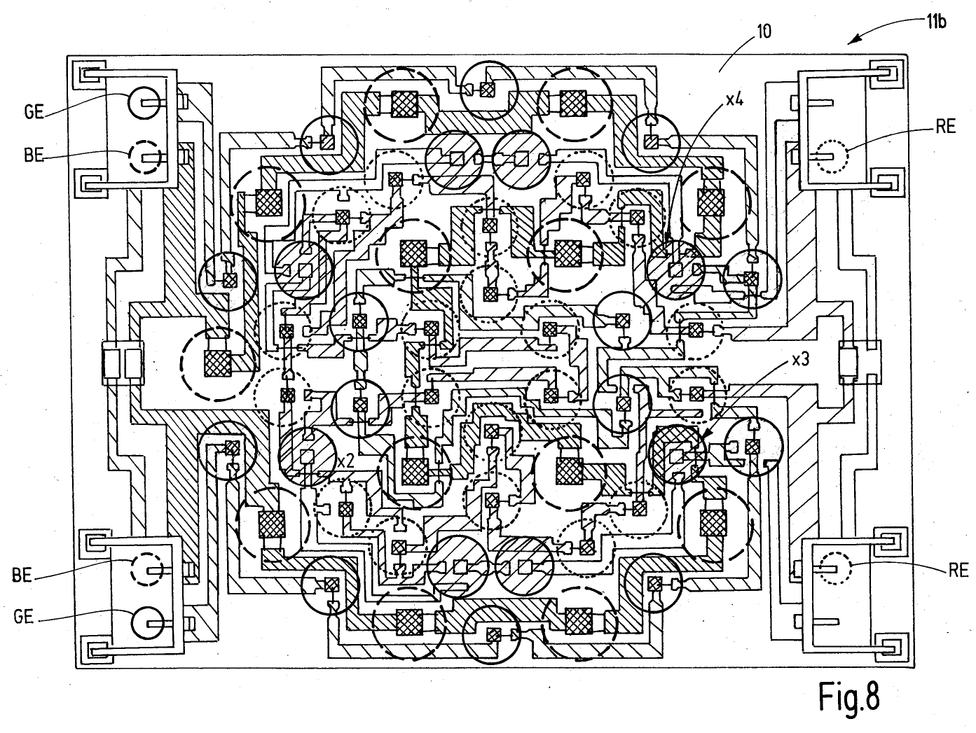

FIG. 8 a further semiconductor light source with the LED support according to FIG. 1 in a further assembly in schematic illustration.

FIG. 1 illustrates schematically an LED support 10 for an LED light source 11, as it is shown in FIGS. 2, 7 and 8 in different assembly variations. An LED light source means in this regard any light source that emits light created in an electronic way (non-thermal illumination). In the illustration of the LED support 10 shown in FIG. 1 strip-shaped conductor tracks without individual reference numerals are illustrated in solid lines. Between the ends of conductor tracks locations for arrangement of semiconductor light sources are provided. They are symbolized by lower case letters. The lower case letter “g” represents green semiconductor light sources. In doing so, it can be green illuminating LED chips or a combination of a semiconductor light source radiating a different wavelength, e.g. a blue or ultraviolet LED chip with a luminescent substance that converts at least a portion of the light emitted from the LED chip in green light.

In accordance blue semiconductor light sources are characterized with the lower case letter “b”. Again it can be blue LEDs or otherwise illuminating LEDs, e.g. in the ultraviolet range that are provided with luminescent substance. Further, red illuminating semiconductor light sources are characterized with the lower case letter “r”, wherein it can be red illuminating LEDs or different illuminating LEDs with red luminescent substance. Finally magenta-colored illuminating semiconductor light sources are provided that are characterized with the lower case letter “m” and that are formed by a respective colored LED chip or a different illuminating LED chip with the luminescent substance.

All green illuminating semiconductor light sources g form a first group G, the semiconductor light sources g of which are numbered from g1 to g14. All blue illuminating semiconductor light sources b form a second group B, the individual semiconductor light sources b thereof are numbered from b1 to b13. All red illuminating semiconductor light sources r form a third group R, the semiconductor light sources r thereof are numbered from r1 to r14. All magenta-colored semiconductor light sources m form a group M, the semiconductor light sources m thereof are numbered from m1 to m14. The reference to the semiconductor light source g, b, r, m without individualizing number applies for any arbitrary semiconductor light source of the group G, B, R, M. Also a reference to a semiconductor light source b, r or m means a reference to any arbitrary semiconductor light source of the respective group B, R or M. The groups can have 13 or 14 elements, as in the above example, or also more or less. The number of elements of the groups can be equal or different. Instead of the colors green, blue, red and magenta, the colors of the groups can also be defined differently. Particularly, one or more groups can also be provided with semiconductor light sources that emit white light. For example, one group can comprise warm white semiconductor light sources, another group can comprise different white, e.g. neutral white semiconductor light sources and additionally or alternatively a third group can comprise cold white semiconductor light sources. A combination of colored and white groups is possible. Preferably each group of semiconductor light sources comprises a uniform color.

Not only the semiconductor light sources g, b, r, m form part of each group G, B, R, M, but additionally conductor tracks that are arranged such that the semiconductor light sources g of the first group G form an electric series connection in an unbranched line section and thus together with a current or voltage source a mesh. The ends of the series connection are accessible at the connections GE for the external connection and for the connection to a current or voltage source.

The semiconductor light sources b1 to b13 and conductor tracks form part of the second group B that form with these semiconductor light sources an electric series connection in an unbranched line section and thus together with a current or voltage source a mesh that can be externally connected at the connections BE. Additionally, semiconductor light sources r1 to r14 and conductor tracks form part of the third group R that allow a series connection of these semiconductor light sources such that they form a third mesh together with a voltage or current source. For connection of the third mesh the two ends of the series connection are provided at the connections RE.

The fourth group M comprises semiconductor light sources m1 to m14 that can be electrically connected with each other in a series connection with respective conductor tracks in an unbranched line section. The conductor tracks and the assigned semiconductor light sources m1 to m14 form a line section extending between the connections ME that forms a mesh together with a current or voltage source connected to the connections ME. Similarly current or voltage sources can be connected at the pair of connections RE, as well as the pair of connections BE as well as the pair of connections GE for completion of the respective mesh.

Reference is made to the groups G, B, R, M as unbranched line sections also if the individual semiconductor light sources g, b, r, m are formed by individual elements (e.g. LEDs) that are connected in parallel.

As it is obvious from FIG. 1, all of the semiconductor light sources g, b, r, m are grouped around a center Z that can be considered substantially in the middle of the LED support 10. In doing so, the semiconductor light sources g, b, r and m are arranged on concentric rings K1, K2, K3 and K4. These rings can be virtual rings as illustrated on which the semiconductor light sources g, b, r, m are positioned such that they are in contact with the circle with a silicon blur or another cover arranged thereon or are located on the circle. Similarly the locations for the semiconductor light sources g, b, r, m define circles or virtual polygons that are arranged concentrically to the center Z. According to the invention, at least two of the virtual rings K1, K2, K3, K4 contain semiconductor light sources of different groups, i.e. different series connections, i.e. line sections. In the present embodiment the first ring K1 contains semiconductor light sources r and m, specifically for example semiconductor light sources r6, r7, r8, r9 as well as m4 and m10. the second ring K2 comprises semiconductor light sources m, g, b, specifically for example the semiconductor light sources m5, m11, g6, g7, g8, g9 as well as b6, b7, b8, b9. The third ring K3 comprises semiconductor light sources r, m, specifically for example the semiconductor light sources r1, r2, r3, r4, r5, r10, r12, r13, r14 as well as m2, m3, m6, m7, m8, m9, m12, m13. The fourth ring K4 comprises semiconductor light sources g, b, specifically the semiconductor light sources g1, g2, g3, g4, g5, g10, g11, g12, g13, g14 as well as b1, b2, b3, b4, b5, b10, b11, b12 and b13. The distribution of the semiconductor light sources g, b, r, m onto the rings K1, K2 and if present K3, K4 can be made such that semiconductor light sources that can create white light by additive mixing respectively are arranged in close proximity to each other as semiconductor light source sub-group (e.g. as triple).

Preferably in each of the rings exclusively or at least predominantly, semiconductor light sources are arranged the color impression of which belongs to colors that are adjacent in the chromatic circle. The first ring K1 comprises semiconductor light sources r with red color and semiconductor light sources m with magenta color. The second ring K2 comprises semiconductor light sources g, b of the colors green and blue as well as individual semiconductor light sources m of the color magenta. Green as well as magenta are positioned near blue in terms of the color impression. The third ring K3 comprises semiconductor light sources r, m of the colors red and magenta. The fourth ring K4 comprises semiconductor light sources b, g of the colors blue and green that are adjacent in the chromatic circle.

With this division a uniform color impression with different brightnesses or also chromaticity coordinates with different currents of the different series connections, i.e. the different line sections, can be achieved.

For further clarification of an embodiment of the invention reference is made to FIG. 2. In this figure all semiconductor light sources g of the first group G without individual characterization are illustrated by solid line circles, the semiconductor light sources b of the second group B are illustrated by dashed circles, the semiconductor light sources r of the third group R are illustrated by dotted circles and the semiconductor light sources m of the fourth group M are illustrated by chain-dotted circles. The circles mark concurrently the approximate size of a material accumulation of cover material applied as blur that encloses the real semiconductor light source, i.e. the respective LED chip and that coats the LED support 10. After curing of such a cover it forms a rounded slub, dome or tubular-like elevation that encloses the semiconductor light source g, b, r, m and the adjacent conductor tracks.

All semiconductor light sources g, b, r, m of the same color of each group G, B, R, M form series connections that form part of different meshes. These series connections are placed on at least two and preferably three of the four rings K1 to K4 respectively. The total length of the conductor tracks measured in current flow direction is as short as possible in each case. This can be particularly realized by providing intersections at which the line sections of the individual series connections intersect. For illustration and clarification of the group membership the conductor tracks of each group are uniformly hatched respectively in FIG. 2:

conductor tracks of the group G—wide hatching from top left to bottom right,

conductor tracks of the group B—tight hatching from top left to bottom right,

conductor tracks of the group R—wide hatching from top right to bottom left,

conductor tracks of the group M—tight hatching from top right to bottom left.

The intersections are formed by bond wires, as it will be explained by way of example in the following at an intersection X1 (FIG. 2) at which the current path of the fourth group M intersects a conductor track of the second group B. It serves to form a bond wire bridge of a bond wire 12 that spans a conductor track leading to the LED chip. The bond wire 12 is only in contact with the conductor tracks of the group M and in fact at the bond locations, but not with the conductor track of the group B.

Additional bond wires contact the chip of the semiconductor light source b6 with a conductor track that is part of the group B. In the following reference is made to the detailed illustration of FIG. 2a. The LED chip 13 being part of the semiconductor light source b6 is placed on an area 14 (chip bonded) that is part of the conductor track of the group B. One or more bond wires 15, 16 that serve for the supply of current to the LED chip 13 extend from the LED chip 13 to an area 17 of the conductor track that also forms part of the group B. The bond wire 12 is attached with its ends on the areas 18, 19 of the conductor tracks by wire bonding that are part of the group M. The distance of the areas 18, 19 from the area 14 is at most as large as the distance of the area 17 from the area 14. In doing so, it is possible to accommodate all bond wires 12, 15, 16 below the uniform cover 20. In addition, a flexible assembly is allowed.

For further clarification of the versatility of the layout of the LED support 10 schematically shown in FIG. 1 and emerging in more detail in FIG. 2, reference is made to the current conductor pattern at the exemplarily referenced semiconductor light source r5 that is individually represented in FIG. 3. Two areas 22, 23 that form part of different lines and different groups and provided for wire bonding adjoin the LED chip 21. Depending on the selected circuitry, a bond wire 24 according to FIG. 3 or 25 according to FIG. 4 can be routed to the area 22 or to the area 23 with which also the respective group memberships of the conductor tracks are defined.

FIG. 5 picks the conductor track layout at the semiconductor light source g7 as an example. As illustrated, the LED chip 26 provided there is arranged on an area 27 of a conductor track that is part of the group G. In direct proximity the conductor track that also forms part of the group G ends with an area 28 for wire bonding. Originating therefrom a bond wire 29 extends to the LED chip 26. In direct proximity to the area 27 a conductor track extends that is part of another group, namely the group M and as illustrated by the dotted line can serve as bond area for a connection wire alternatively the bond wire 29. In addition a bond wire bridge similar to FIG. 2a can be provided that, however, now is part of the group R. Conductor tracks of the group R end at both sides of the conductor track of group G with small distance thereto and are connected with each other there by means of a bond wire 30 that spans the conductor track of the group G.

A further modification of a possible conductor track configuration is illustrated in FIG. 6. It is finally based on the configuration according to FIG. 5, wherein parts with the same function are provided with the same reference signs and reference is made to the description above. Alternative bond paths are indicated by dotted lines.

All intersections of the LED light source 11 have in common that the bond wire for intersection of a conductor track (e.g. bond wire 12 at the semiconductor light source b6 or also the bond wires 30 in the configurations of FIGS. 5 and 6) span the conductor track forming part of another group respectively and leading to an area 14, 27 provided for chip bonding. Due to this measure, namely the arrangement of the bond wire bridge adjacent to the chip bond area 14, 27, the bond wire bridge is placed in close proximity to the adjacent LED chip and in doing so, it is achieved that the bond wire 12, 30 serving as wire bridge is enclosed by the cover 20 applied for protection of the LED chip. In addition, it is guaranteed that the cover material reliably flows under the bond wire 12, 30 such that the cover material forms an insulation between the bond wire 12, 30 and the bridged conductor track placed underneath.

FIG. 7 illustrates an LED light source 11a with modified assembly. While the LED light source according to FIG. 2 comprises semiconductor light sources (e.g. LED chips) that emit in the blue or the near ultraviolet and that are provided with a cover comprising luminescent substance, FIG. 7 illustrates an LED light source with different colored LED chips and covers without luminescent substance. The created colors are again indicated by respective line patterns. The line membership to the different groups R, B, M is illustrated by a group specific hatching. Non-hatched lines are without function, in this embodiment only three groups are present. Different use of the bond schema and the present layouts of the support 10 becomes clear at the semiconductor light source r5 and its two neighboring light sources. Apart therefrom the above description applies accordingly.

In all embodiments the groups R, G, B, M can comprise semiconductor light sources r, g, b, m, as for example in the colors red, green, blue, magenta. Alternatively, the semiconductor light sources r, g, b, m can emit also other colors or white light with different light temperatures independent from its characterizing letter.

FIG. 8 illustrates a further alternative assembly variation of the LED support 10 for an LED light source 11b. The hatched circles mark unequipped board locations. The remaining locations can be equipped as explained above. However, preferably at least on some of the non-equipped assembly locations cover material can be present and in fact particularly at least on those locations at which a bond wire bridge is provided, as for example at the intersections that are characterized in FIG. 8 with X2, X3 and X4. The conductor tracks of the three groups are again characterized by individual hatching.

An inventive LED support 10 for at least two groups R, G, B, M of semiconductor light sources r, g, b, m connected in series is provided with conductor tracks that allow series connections of the semiconductor light sources r, g, b, m of each of the groups R, G, B, M. The series connections with the connected voltage or current sources form independent meshes that are arranged on the LED support 10 in a line pattern that is not free of intersections. This allows the arrangement of the semiconductor light sources r, g, b, m on rings K1, K2, K3, K4 that are concentric to each other, wherein at least two of these rings K1 to K4 comprise semiconductor light sources r, g, b, m that form part of at least two of the different groups R, G, B, M. Necessary line bridges are formed by bond wire bridges that are directly adjacent to the LED chips and span a line that leads to a chip bond area.

With this measure a homogeneous brightness and color distribution over the area of the LED light source is achieved also, if the brightness as well as the color composition are varied by variation of the individual currents flowing through the series connections.

List of Reference Signs:

| | |
|---|---|
| 10 | LED support |
| 11, 11a, b | LED light source |
| G | first group |
| g | semiconductor light sources of the first |
| | group |
| B | second group |
| b | semiconductor light sources of the second |
| | group |
| R | the third group |
| r | semiconductor light sources of the third |
| | group |
| M | fourth group |
| m | semiconductor light sources of the fourth |
| | group |
| GE | connections of the first series connection |
| BE | connections of the second series connection |
| RE | connections of the third series connection |
| ME | connections of the fourth series connection |
| Z | center |
| K1 | first ring |
| K2 | second ring |
| K3 | third ring |
| K4 | fourth ring |
| 12 | bond wire |
| 13 | LED chip |
| 14 | area for chip bonding |
| 17-19 | area for wire bonding |
| 20 | cover |
| 21 | LED chip |
| 22, 23 | area for wire bonding |
| 24, 25 | bond wires |
| 26 | LED chip |
| 27 | area for chip bonding |
| 28 | area for wire bonding |
| 29, 30 | bond wire |
| 31 | |
| X0-X4 | intersections |

1. An LED support (10) for at least two groups (R, G, B, M) of semiconductor light sources (r, g, b, m) connected in series with each other, comprising:
a support body that comprises an electric insulating surface,
a first series of conductor tracks arranged on the electric insulating surface that can are configured to be connected to a first group (G) of the at least two groups of semiconductor light sources (g) in order to connect them electrically in a first series connection,
a second series of conductor tracks arranged on the electrical insulating surface that are configured to be connected to a second group (B) of the at least two groups of semiconductor light sources (b) in order to connect them electrically in a second series connection,
wherein the first and second series of conductor tracks are arranged such that the semiconductor light sources (g) of the first group (G) and the semiconductor light sources (b) of the second group (B) are arranged in at least two rings (K2, K4) that are concentric to each other, wherein individual ones of the semiconductor light sources (g, b) of both the first and second groups (G, B) are arranged in at least one of the at least two rings (K2, K4).

2. The LED support according to claim 1, wherein individual ones of the semiconductor light sources (g, b) of both the first and second groups (G, B) are arranged in both of the at least two rings (K2, K4).

3. The LED support according to claim 1, wherein the first and second series connections intersect each other at least at one intersection (X0).

4. The LED support according to claim 1, wherein the conductor tracks in each of the first and second series connections comprise areas (14, 27) for mechanical receipt and electric connection of semiconductor light sources (13, 26) as well as areas (17, 22, 23, 28) for receipt of at least one connection wire (15, 16, 24, 25, 29) that is in connection with a respectively assigned semiconductor light source (13, 26).

5. The LED support according to claim 3, wherein at least two conductor tracks of one of the first and second series connections comprise areas (18, 19) at the at least one intersection (X0-X4) configured to be connected by a bond wire bridge between which a conductor track of the other of the first and second series connections extends.

6. The LED support according to claim 5, wherein the conductor track which extends between the areas (18, 19) at the at least one intersection (X0-X4) and extends underneath a bond wire bridge leads to an area (14, 27) configured for mechanical receipt and electric connection of a semiconductor light source (13, 26).

7. The LED support according to claim 5, wherein a bond wire bridge connecting the areas (18, 19) at the at least one intersection (X0-X4) is arranged in direct proximity to a semiconductor light source (13, 26) such that a transparent cover (20) covers the semiconductor light source (13, 26) as well as the bond wire bridge.

8. The LED support according to claim 5, wherein the areas (18, 19) configured to be connected by the bond wire bridge are arranged at a distance to the adjacent area (14) for mechanical receipt and electric connection of a semiconductor light source (13) that is not larger than the distance between an area (17) for receipt of a connection wire (12) and the adjacent area (14) for mechanical receipt and electric connection of the semiconductor light source (13).

9. An LED light source with the LED support according to claim 1, further comprising semiconductor light sources (g, b) arranged thereon and individually arranged covers (20) disposed on individual ones of the semiconductor light sources (g, b).

10. The LED light source according to claim 9, wherein the semiconductor light sources (g) of the first group (G) illuminate with a different spectral composition than the semiconductor light sources (b) of the second group (B).

11. The LED light source according to claim 9, wherein individual ones of the semiconductor light sources (g) of the first group (G) and/or individual ones of the semiconductor light sources (b) of the second group (B) are provided with covers (20) that are formed by cured drops of a cover material.

12. The LED light source according to claim 9, wherein individual ones of the covers (20) of the semiconductor light sources of the first group (G) and/or the second group (B) comprise a cover material comprising a luminescent substance.

13. The LED light source according to claim 9, wherein a bond wire bridge is provided at an intersection (X0) comprising a bond wire (12) that is connected with one end to a conductor track that is part of the first group (G) of semiconductor light sources that extends over a conductor track that is part of the second group (B) of semiconductor light sources and that is connected with its other end to a conductor track that is part of the first group (G) of semiconductor light sources.

14. The LED light source according to claim 13, wherein the bond wire bridge and an adjacent semiconductor light source (g7) are enclosed by a same cover (20) that is applied on a body of the LED support (10) as a primary chip cover.

15. The LED light source according to claim 14, wherein electric insulating cover material is arranged between the bond wire (12) of the bond wire bridge and the conductor track bridged by it.
